(19) United States
(12) Patent Application Publication
(10) Pub. No.: US 2012/0266431 A1
(43) Pub. Date: Oct. 25, 2012

(54) METHOD FOR CONTROLLING A BATTERY AND DEVICE FOR IMPLEMENTING THE METHOD

(75) Inventors: Elke Hahn, Dresden (DE); Joerg Kaiser, Eggenstein (DE); Andreas Gutsch, Luedinghausen (DE)

(73) Assignee: Li-Tec Battery GmbH, Kamenz (DE)

(21) Appl. No.: 13/388,785

(22) PCT Filed: Jul. 28, 2010
(86) PCT No.: PCT/EP2010/004634

§ 371 Date: Jul. 10, 2012

(30) Foreign Application Priority Data
Aug. 4, 2009 (DE) 10 2009 036 083.2

(51) Int. Cl. G01N 27/416; G01R 31/36; G06F 19/00

(52) U.S. Cl. 29/407.05; 324/434; 700/297

(57) ABSTRACT

The control of the operational states of a battery or the electrochemical cells thereof is implemented on the basis of an evaluation of said operational states. Said evaluation is obtained by means of approximation functions with which the evaluation of second operational states are obtained by interpolating measuring data of first operational states.

The present invention concerns a method and a device for controlling the operating conditions of a battery comprising electrochemical cells. By virtue of the sensitivity of electrochemical energy storage devices, in particular, such as lithium-ion cells and lithium-ion batteries, to operating conditions incurring stress and damage, and the consequential accelerated ageing of these energy storage devices, these are usually equipped with a so-called battery management system, that is to say, with protective circuitry, which avoids the operating conditions that incur damage, such as can arise as a result of utilising a battery or cell outside prescribed operating regimes, as defined, for example, by voltage limits, current limits or temperature limits.

U.S. Pat. No. 5,617,324 describes a device for the measurement of the residual battery capacity, which employs a device for calculating the voltage-current relationship to detect the “dispersive” terminal voltages and discharge currents of a battery. A device is used to calculate an approximately linear function between terminal voltages and discharge currents and to calculate a correlation coefficient between these factors, in order to decide whether a calculated correlation coefficient, reduced by a negative reference value, can be continuously calculated.

U.S. Pat. No. 6,366,054 describes a method for determining the state of charge (SoC) of a battery by measuring an open circuit voltage (OCV) in the non-operational state of chemical and electrical equilibrium, or in a non-equilibrium state, in which the battery, after completing a charging or discharging activity, once again approaches an equilibrium state. Here a first algorithm is introduced in order to correlate the open circuit voltage in equilibrium with the state of charge, in which this measurement is conducted. A second algorithm serves the purpose of predicting the equilibrium open circuit voltage of a battery on the basis of the open circuit voltage, its rate of alteration with time, and the battery temperature in the non-equilibrium phase.

U.S. Pat. No. 7,072,871 describes a system for determining the state of health of batteries with an adaptive component. The system tests a battery by measuring a number of electrochemical parameters, and makes use of fuzzy logic to calculate the state of health of the battery.

EP 1 109 028 describes a method for monitoring the residual charge and the service capability of a battery, in which at least two current-voltage measurements are conducted in the high current regime on the battery while under load. The first current-voltage measurement is measured at a first point in time at a first loading condition for the battery. A second current-voltage measurement is conducted at a second point in time at a second loading condition for the battery. What is important here is that the loading condition for the battery has altered as a result of the current drawn. The current-voltage measurements provide a first measurement point and a second measurement point. A straight-line interpolation is positioned through the two measurement points and its point of intersection with a limiting voltage level (UGr) is determined. This point of intersection is characterised in terms of a so-called limiting current (IGr). The limiting voltage level is determined from the minimum voltage that the connected consumer loads require in order to function without fault. The limiting voltage level is therefore prescribed by the technical design of the battery network and is known.

DE 102 08 652 describes a method for recording the state of charge of a battery, in which at least two pairs of measurements of voltage and current are recorded, and are corrected to the values that ensue in the thermal steady state. These recorded measurements are interpolated and an open circuit voltage value and state of charge are determined by means of a prescribed relationship between the open circuit voltage determined and the state of charge.

DE 197 50 309 describes a method for determining the start-up capability of a starter battery of a motor vehicle, in which the average value of the voltage drop during start-up of the engine is measured and compared with voltage values from a family of characteristics, which consist of measured voltage drops and related battery and engine temperatures.

DE 40 07 883 describes a method and a battery testing unit for determining the condition of a lead battery. Here in a discharge cycle the battery is brought into a stable condition, and is then discharged with a high discharge current. With the aid of comparison curves stored for the appropriate type of battery the start-up capability or loss of start-up capability is displayed on the basis of the measurements determined on the stabilised battery, and after the flow of the high discharge current, while taking the temperature into account.

Battery management systems make use of such methods, or similar methods or devices, to control or regulate battery operating conditions. Often these battery management systems or protective circuits engage by switching off the battery, or a cell in the battery, or by limiting the power output of the battery to a level that will not damage the cells. As a result, however, the options open to the user in the utilisation of the battery can be restricted in an undesirable manner.

The object of the present invention is to specify an improved method for controlling a battery, or an improved device for executing such a method. This object is achieved by means of a method or a device for controlling the operating conditions of a battery, or by means of a method for configuring a battery in accordance with one of the independent claims.

In accordance with the invention provision is made that the control of the operating conditions of a battery or its electrochemical cells takes place on the basis of an assessment of these operating conditions. This assessment is obtained with the aid of approximation functions, with the aid of which assessments are determined for a second set of operating conditions, for which no, or no complete, measured data concerning the behaviour of the battery are available, by means of interpolation from measured data for a first set of operating conditions, for which the measured data concerning the behaviour of the battery are available.

A battery in the context of the present invention is a series and/or parallel circuit comprising a multiplicity of cells, or also just an individual cell. A cell is here understood to be a “galvanic cell”, that is to say, an electrochemical energy storage device. Here the cells can take the form of rechargeable secondary cells or non-rechargeable primary cells. In what follows, if nothing else ensues from the context, the term battery, is occasionally also used to simplify matters for an individual cell, which can indeed be thought of as a single-cell battery. If in this application reference is made to an energy storage device or an electrochemical energy storage device, what is meant by this is an individual cell, or a battery comprising a multiplicity of cells.

An operating condition of an individual cell, or a battery comprising a multiplicity of electrochemical cells, is characterised by operating condition factors. Examples for such operating condition factors are the voltage, the resistance (internal resistance), the temperature, the charge current or the discharge current. Other operating condition factors are familiar to the person skilled in the art and can arise in the context of examples of embodiment of the present invention.

An operating condition is characterised by means of a set of suitable operating condition factors, such as e.g. charge currents, discharge currents, voltages, resistances, temperatures, or similar. The term “operating condition factor” corresponds here to the term “operating parameter” of a cell or battery that is likewise familiar in this field of technology. Which sets of operating condition factors (operating parameters) are in each case suitable for characterising an operating condition of a cell or battery and can therefore be advantageously used depends on the underlying technology that is being considered, and on the electrochemical models that are called upon in each case for the characterisation of this technology in physical terms.

In the present context the assessment of an operating condition should be understood as a qualitative or quantitative classification that assigns a measure or an indicator to one or a plurality of possible or actual sets of operating conditions of a battery for the ageing or damage incurred by the battery or its cells. Such assessments can consist of ageing curves for individual cells or batteries that have been obtained from measurements for a limited first set of operating conditions. Examples for ageing curves are functional classifications of data, which characterise the ageing or damage incurred in a first set of operating conditions. By means of interpolation between (or by means of extrapolation from) these measurements, assessments can then also be derived for a second set of operating conditions, for which no measurements have been conducted. For the sake of semantic convenience the term interpolation —if nothing to the contrary ensues from the context—will be deemed always to include extrapolation, particularly since the two methods are not fundamentally different from the mathematical or technical point of view.

The control of the operating conditions of a battery or cell is to be understood to include all measures with which the operating condition factors of the controlled battery or cell can be governed. These include in particular a reduction of the loading on a battery or cell, the extraction of a cell from a battery pack, its cooling or other measures that are suitable for governing the operating conditions of a battery.

First sets of operating conditions in the context of the present invention are thereby operating conditions for which measured data are available for the behaviour of the battery or cell in such operating conditions, in particular concerning the ageing behaviour of the battery or cell in such operating conditions. In contrast, second sets of operating conditions are operating conditions, which as a result of the type of utilisation of a battery, or the cell of this battery, or this cell, can be assumed, for which however such measured data are not available.

Approximation functions in the context of the description of the present invention are parameterised functions, that is to say, functions that depend on one parameter or on a plurality of parameters and on operating condition factors, which on the basis of their mathematical properties are suitable for approximating a larger number of measured data, which have been determined for the first set of operating conditions of a battery, by means of a suitable selection of their parameters, so that the factors corresponding to the measured data for a second set of operating conditions for the battery, in which these measured data are not available, can be determined with the aid of these approximation functions by means of an interpolation. Approximation functions are functions of operating condition factors and (further) parameters. The approximation functions can be linear or non-linear functions of these variables. Non-linear functional dependencies open up a much greater space of possible functional forms and thus a significantly greater flexibility than a limitation to linear functional dependencies. The price for this higher flexibility must often be paid for in the form of an increased computational effort in the determination of the optimal parameter values.

These parameters, on which the approximation functions in addition to the operating condition factors depend, and their values are determined such that the approximation functions “approximate” the measured data as well as possible, are to be differentiated conceptually from the “operating parameters”. The so-called operating parameters are operating condition factors, that is to say, they characterise operating conditions. The parameters of the approximation functions are not operating condition factors; their values are selected such that the approximation functions represent the measured data as well as possible. This statement is not affected by the fact that the functional dependence of the approximation functions on their variables (operating condition factors and parameters) can be motivated by physical or electrochemical modelling techniques, in which the significance of operating condition factors corresponds to an individual parameter or a plurality of parameters, which then however are not observed (i.e. are not measured) within the framework of the application of these particular approximation functions.

Measured data in the context of the description of the present invention are operating condition factors and/or other preferably physical, technical or chemical factors that are suitable for characterising the behaviour, in particular the ageing behaviour or the damage incurred by a cell or battery in an operating condition. Examples for such measured data are the capacity, in particular the residual capacity, the current-carrying capacity, for example characterised by the alteration of the terminal voltage with the discharge current, or similar factors.

Advantageous further developments of the invention are the subjects of dependent claims.

The invention is elucidated in more detail in what follows with the aid of preferred examples of embodiment.

The invention assumes that for different operating conditions of cells or batteries, which are specified by suitable operating condition factors, such as e.g. charge currents, discharge currents, voltages, resistances, temperatures or similar, the ageing behaviour of individual cells, for example, of so-called lithium-ion cells or whole packs (“batteries”) of a plurality of such cells has been measured. Since such measurements for practical reasons are always only possible for a limited (finite) number of operating conditions, no continuous curves or—in the significant case in practice of a plurality of operating condition factors—(hyper) surfaces of functions, can be determined in this manner, which describe the ageing behaviour for any operating conditions.

Instead measured values are determined for a relatively few selected operating conditions, used for the measurements, from which a preferably quantitative measure can be derived for the ageing or damage incurred by cells or whole batteries under the respective operating conditions. Here this need not necessarily take the form of a quantitative measure, that is to say an established measure in numerical terms, instead it can take the form of a qualitative assessment of the ageing behaviour or the ageing condition or the damage incurred by an energy storage device, which e.g. can be characterised by means of adjectives such as “severe”, “weak”, “old”, “new”, or indices assigned to such adjectives.

For example, U.S. Pat. No. 7,072,871 describes a system for determining the state of health of batteries with an adaptive component. The system tests a battery by measuring a number of electrochemical parameters, and makes use of fuzzy logic to calculate the state of health of the battery. Here, as is characteristic for fuzzy logic, qualitative assessments, such as “R-GOOD”, “R-EXCELLENT” or “R-POOR” are undertaken with the aid of so-called “membership functions” of battery conditions, which for example (see FIG. 5B of U.S. Pat. No. 7,072,871) are characterised by numerical values of the internal resistance or other operating condition factors. FIG. 5A of U.S. Pat. No. 7,072,871 shows the general principle of such qualitative assessments made with the aid of fuzzy logic methods.

Although, as a rule, quantitative assessments of operating conditions have greater significance than qualitative assessments the present invention is not limited to one of the two methods, but rather can be used in conjunction with either of these two methods. For the present invention, it is important that on the basis of such measurements for a first set of operating conditions, indicators, or measures, or measured values can be derived for the ageing behaviour of the energy storage device, i.e. for the battery or an individual cell.

In general, the number in the first set of operating conditions that are available for the measurements will be much less than the number of operating conditions for which a user wishes to operate the energy storage device concerned in a particular application. For an operational battery management system, which is designed to allow a user to operate a battery in the most flexible manner possible, controls are therefore required that also enable control under operating conditions for which no measured data are available. If, as in the present case, control is to be undertaken on the basis of an assessment of the ageing behaviour or the damage incurred by an energy storage device, it is also necessary to employ an appropriate assessment for such operating conditions under which an assessment based on measurements was not possible, or has not been undertaken.

The present invention—in contrast to some methods of known art, some of which have been referred to in the introduction to the description—does not assume that such assessments must be determined as a result of high current measurements, although such measurements are also not excluded within the framework of the present invention. However, high current measurements place more load on the battery than low current measurements in all circumstances, moreover, they are associated with non-negligible energy losses affecting the actual application of the battery, so that in many cases it appears to be a desirable to avoid such high current measurements.

The present invention now envisages the determination of such an assessment for the second set of operating conditions, in which no measurements have been undertaken, by means of an interpolation of assessments for the first set of operating conditions. In accordance with the invention, these interpolations are to be undertaken with the aid of approximation functions, which describe the ageing behaviour or damage characteristics of energy storage devices for any technically possible, or at least for any technically and practically relevant, operating conditions, and which reproduce as well as possible the measured assessments for the first set of operating conditions.

As is fundamentally of known art to the person skilled in the art in many fields of technology, such approximation functions are usually adapted by the minimisation of an error measure for the measured data, in that the error, i.e. the deviation between the function values of the approximation functions and the measurements for the first set of operating conditions, is minimised. Under the often plausible assumption, applicable in many important cases, that the assessments are continuous functions of the operating condition factors, the values of the approximation functions for operating condition factors, which correspond to the second set of operating conditions, for which, that is to say, no measurements are available, should accurately describe the actual circumstances of the ageing behaviour or the damage incurred under such operating conditions. The deviations between the values of the approximation functions and the measured data are determined by the determination of the approximation functions by variation of their parameters. Here the parameters are adjusted such that the error measure used, for example, the sum of the squares of the deviations (if necessary, suitably weighted), or a similar error measure, is a minimum.

Where the assumption of the continuous dependence of the approximation functions on the operating condition factors is not fulfilled, suitably selected types of approximation functions can be deployed, whose discontinuities, pole positions, or other types of singularities have been positioned by a suitable selection of their parameters such that they reproduce these actual circumstances with a sufficient approximation.

A widely used method for the determination of suitable parameter values of approximation functions in the case of numerical values is, for example, the minimisation of the sum of the least squares of the errors. Depending upon the application, more progressive methods are also known to the person skilled in the art, in which different weightings are possible for the individual measured data, which are designed to take account of the reliability or susceptibility to error of the measured data in a commensurate manner. Within the framework of the present description of the present invention this subject will not be pursued in any further detail. Instead, reference should be made to the extensive literature on numerical approximation.

The person skilled in the art often finds suitable types of functions for approximation functions on the basis of physical or electrochemical modelling techniques, which imply certain “legitimate” relationships between operating condition factors of batteries or individual cells, which are usually only approximately valid. One example of such “legitimate” relationships may be the so-called Peukert equation (Vieweg, “Handbuch Kraftfahrzeugtechnik [Handbook of Motor Vehicle Technology]”, edited by Hans-Hermann Braess, Ulrich Seiffert and associates, Hans-Hermann Braess, Edition: 5, published by Vieweg-Teubner-Verlag, 2007, ISBN 3834802220, 9783834802224, 923 pages, for example page 330), which provides an empirical relationship between the extractable charge of a battery and the discharge current.

In principle non-numerical assessments can also be interpolated by means of approximation functions. In the present description the fundamentals of these options will not be pursued in any further detail. instead, reference is made to the relevant literature, for example, to the monograph “Computing with Words in Information” by Lofty A. Zadeh and Janusz Kacprizyk, published by Springer Verlag 1999, ISBN 379081217X, or to the monograph “Introduction to Approximation Theory” by Eliot Ward Cheney, American Mathematical Society, Edition 2, published by the AMS Bookstore, 1998, ISBN 0281813749.

With the aid of such approximation functions, it is also possible to design (“configure”) battery systems comprising a plurality of individual cells systematically in accordance with the individual requirement profiles of users with reference to the electrical power output or their service life, in that the cells of a battery are connected together in a suitable manner in parallel and/or in series, without thereby dimensioning the battery system in an uneconomical manner (“over-dimensioning”).

Moreover a battery management system, or the protective electronics contained within it, can be configured with the aid of the approximation functions obtained in the manner indicated above such that it detects operating conditions that place above average loads on the cells of a battery system and/or cause them to age undesirably quickly.

Building on these principles it is possible, in particular in the case of batteries that are allocated to a user on loan for a limited time, to develop appropriate dynamic pricing models, in which the user (“lessee”) has to pay a price that is dependent on the damage or ageing that a battery has incurred as a result of his usage. This user therefore has a higher flexibility when using the battery than if the battery management system or the protective electronics were to simply switch off the battery or limit its utilisation. Instead the user can himself decide in what manner her wishes to use the battery, but must pay a higher price for the utilisation of the battery if corresponding damage or increased ageing are linked with his utilisation.

In a preferred form of embodiment of the invention a quantitative measure for the ageing or damage incurred by cells, or batteries of cells, is called upon for the assessment of an operating condition. Examples for such quantitative measures are the absolute or relative residual service life, the absolute or relative available capacity, or similar factors, which are suitable for describing the ageing status of, or damage incurred by, an energy storage device.

Preferably these measures give the ageing or damage incurred per unit of time in the respective operating condition to which they are assigned. This preferred variant of embodiment of the invention has the advantage that during, after or before passing through a sequence of operating conditions the (integral) ageing or damage incurred by the battery or cell caused by passing through this sequence of conditions can be established by integration over time of these condition-specific ageing rate measures. In this manner it is possible to instruct the user accordingly when planning his usage concerning its consequences for the ageing of the battery, and to impose on him as required the costs for the usage planned or executed by him.

This instruction or information given to the user concerning the consequences of his utilisation of the battery for the ageing of the latter can also take place in an automatic manner in the course of usage and preferably such that a programmed usage control evaluates this information and uses it to optimise objectives prescribed by the user, or to observe limiting conditions.

In accordance with the invention the control is preferably designed such that a quantitative measure for the ageing or damage incurred by cells, or batteries of cells, is minimised. It is however also possible to execute the minimisation such that an operating condition is sought in which the rate of ageing or damage per unit of time is minimal, or less than in a current operating condition that is actually assumed. Another option consists in minimising a measure integrated over time for the ageing or damage incurred by the energy storage device. Combinations of these procedures are also possible. Which procedure to choose depends on the particular application in question.

Applications are also possible in which the exclusive minimisation of ageing criteria or damage incurred by an energy storage device is not advantageous. In such situations a target figure is preferably optimised, which alongside at least one quantitative measure for the ageing or damage incurred by cells comprises at least one further function of operating condition factors for the battery. Such more complex target figures can ensue, for example, if limiting conditions are to be observed in the control, such as e.g. the criterion that the power output must not be allowed to fall below or exceed a certain figure. Again in the case of other applications it is possible that the target figure to be optimised is composed of a combination of a measure for the ageing or damage on the one hand, and another performance measure, for example the power output, the residual battery capacity, or similar factors.

In many forms of embodiment of the present invention battery conditions are preferably characterised by at least one of the operating condition factors of battery voltage, resistance, temperature, charge current or discharge current. Depending upon the battery technology that is being used other operating condition factors can be suitable for the characterisation of the operating condition of an energy storage device. The invention is not limited to an application in conjunction with lithium-ion cells or batteries comprising such cells, but can in principle also find application with other battery technologies.

In some preferred forms of embodiment of the invention it is desirable to control the battery such that individual cells can be controlled, for example, can be switched on or off. In such forms of embodiment of the invention it is advantageous to characterise the battery condition by means of operating condition factors of individual cells of a battery, so that the control can be designed such that it is able to switch individual cells in a battery pack on or off as a function of their operating condition.

For the execution of the method for controlling the operating conditions of a battery, a control device can be introduced in accordance with the invention, which has a processor and a memory. The processor processes a control program, which executes the control of the operating conditions on the basis of an assessment of the operating conditions. In the memory are stored, amongst other items, the approximation functions, preferably in the form of their parameter values.

The present invention can, moreover, be implemented by means of a method for the configuration of a battery comprising electrochemical cells, in which an optimal combination of cells is determined in terms of series and/or parallel circuitry on the basis of an assessment of operating conditions of the battery and/or individual cells. This assessment is obtained with the aid of approximation functions, with the aid of which assessments for a second set of operating conditions are determined by means of interpolation from measured data for a first set of operating conditions.

For the configuration of a battery, the approximation functions. and an electrical utilisation profile, which has been agreed with the user or defined by the latter, and which describes the customary or intended deployment of the battery by this user, are preferably used in order to determine, with the knowledge of further parameters of the application, such as e.g. the operating time, an optimal serial and/or parallel circuitry for the individual cells. In this manner it is possible to fulfil the user's requirements set down in the utilisation profile, thereby at the same time to protect the battery from inadvertent ageing processes or damage, and at the same time to avoid an expensive over-dimensioning of the battery.

In the utilisation provision (leasing) of batteries for a user it is usual to define a leasing rate (utilisation charge) on the basis of a utilisation profile and an agreed contract period. If it now happens that the user (customer) utilises the battery in an operating condition in which it ages or incurs damage at a faster rate than agreed or defined in the contract, or before the end of the contract period, this is detected by the battery management system in accordance with the present invention. The user can now decide whether he wants the protective electronics to engage and switch off the battery or limit its power output to a level at which no damage is incurred; however, he also has the option of utilising operating conditions, which deviate from the standard of the agreed utilisation profile, in turn for a surcharge on the leasing rate. In this manner the user has a higher level of flexibility and can also utilise the battery beyond the operating conditions foreseen in the contract.

1-12. (canceled)

13. A method for controlling the operating conditions of a battery, comprising electrochemical cells, in which control of operating conditions takes place on the basis of an assessment of the operating conditions, comprising:
obtaining the assessment based on approximation functions, the approximation functions being used to determine a second set of operating conditions for which measured data concerning the behaviour of the battery is lacking, the second set of operating conditions being determined by interpolating measured data for a first set of operating conditions for which measured data concerning the behaviour of the battery is available,
wherein assessment of an operating condition includes at least one quantitative measure for ageing or damage incurred by the electrochemical cells under the operating condition.

14. The method in accordance with claim 13, further comprising:
minimizing a quantitative measure for the ageing or damage incurred by the electrochemical cells.

15. The method in accordance with claim 13, further comprising:
optimizing a target figure, the target figure in conjunction with at least one quantitative measure for the ageing or damage incurred by the electrochemical cells includes at least one further function of operating condition factors of the battery.

16. The method in accordance with claim 15, wherein operating condition factors include at least one of the operating condition factors of voltage, resistance, temperature, charge current or discharge current.

17. The method in accordance with claim 13, further comprising:
optimizing a target figure, the target figure in conjunction with at least one quantitative measure for the ageing or damage incurred by the electrochemical cells includes at least an electrical power output of the battery, a probable residual service life, or a residual capacity of the battery.

18. The method in accordance with claim 13, wherein the approximation functions include approximation functions which have been obtained by approximation of parametric functions on measured ageing data, the ageing data being measured under predetermined first operating conditions of the battery.

19. The method in accordance with claim 13, further comprising:
characterizing a battery condition based on operating condition factors of individual electrochemical cells of the battery; and
switching individual electrochemical cells in and out of a battery pack based on the operating condition of the electrochemical cell.

20. The method in accordance with claim 13, wherein assessments of operating conditions are obtained based on non-linear approximation functions.

21. The method in accordance claim 13, wherein assessments of operating conditions are obtained based on approximation functions, the approximation functions having a functional form specified by physical or chemical models via functional relationships between operating condition factors of the battery.

22. A device for controlling operating conditions of a battery including electrochemical cells, comprising:
a processor to process a control program, which executes control of the operating conditions on the basis of an assessment of the operating conditions, wherein the assessment is obtained based on approximation functions to determine assessments for a second set of operating conditions using interpolation from measured data for a first set of operating conditions; and
a store to store parameter values of approximation functions,
wherein assessment of an operating condition includes at least one quantitative measure for ageing or damage incurred by the electrochemical cells in the operating condition.

23. A method for the configuration of a battery, including electrochemical cells, in which an optimal combination of electrochemical cells is determined via series and/or parallel circuitry on the basis of an assessment of operating conditions of the battery and/or individual electrochemical cells, comprising:
obtaining the assessment based on approximation functions, the approximation functions being used to determine assessments for a second set of operating conditions using interpolation from measured data for a first set of operating conditions,
wherein assessment of an operating condition contains at least one quantitative measure for ageing or damage incurred by cells in the operating condition.
